(19) United States
(12) Patent Application Publication
(10) Pub. No.: US 2025/0391011 A1
(43) Pub. Date: Dec. 25, 2025

(54) SYSTEM AND METHOD FOR IMAGE RESOLUTION CHARACTERIZATION

(71) Applicant: ASML Netherlands B.V., Veldhoven (NL)

(72) Inventor: Xinan LUO, San Jose, CA (US)

(73) Assignee: ASML Netherlands B.V., Veldhoven (NL)

(21) Appl. No.: 18/876,162

(22) PCT Filed: Sep. 6, 2023
(86) PCT No.: PCT/EP2023/074498

§ 371 Date: Dec. 17, 2024

Related U.S. Application Data
(60) Provisional application No. 63/409,049, filed on Sep. 22, 2022.

(51) Int. Cl. G06T 7/00; G06T 5/80

(52) U.S. Cl. CPC G06T 7/001; G06T 5/80; G06T 2207/10061; G06T 2207/20056; G06T 2207/30148

(57) ABSTRACT

Systems, apparatuses, and methods include a providing a raw image of a sample; observing a pixel size of the raw image; converting the raw image into a transformed image by applying a Fourier transform to the raw image; applying a function, based on the pixel size, to the transformed image; and determining a key performance indicator of a resolution of the raw image based on results of the applied function.

### CROSS-REFERENCE TO RELATED APPLICATIONS

This application claims priority of U.S. application 63/409,049 which was filed on Sep. 22, 2022 and which is incorporated herein in its entirety by reference.

### FIELD

The description herein relates to the field of inspection and metrology systems, and more particularly to systems for image resolution characterization.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused on locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide apparatuses, systems, and methods for image resolution characterization. In some embodiments, systems and methods may include providing a raw image of a sample; observing a pixel size of the raw image; converting the raw image into a transformed image by applying a Fourier transform to the raw image; applying a function, based on the pixel size, to the transformed image; and determining a key performance indicator of a resolution of the raw image based on results of the applied function.

In some embodiments, systems and methods may include providing an image of a sample; observing a pixel size of the image; converting the raw image into a transformed image; applying a function, based on the pixel size, to the transformed image; and determining a key performance indicator of a resolution of the image by applying the function to the transformed image.

### BRIEF DESCRIPTION OF THE DRAWINGS

FIG. 1 is a schematic diagram illustrating an exemplary electron beam inspection (EBI) system, consistent with embodiments of the present disclosure.

FIG. 2A is a schematic diagram illustrating an exemplary multi-beam system that is part of the exemplary charged particle beam inspection system of FIG. 1, consistent with embodiments of the present disclosure.

FIG. 2B is a schematic diagram illustrating an exemplary single-beam system that is part of the exemplary charged particle beam inspection system of FIG. 1, consistent with embodiments of the present disclosure.

FIG. 3 is a schematic diagram of an exemplary key performance indicator (KPI) determination system, consistent with embodiments of the present disclosure.

FIG. 4 shows exemplary images and graphs generated by a KPI determination system, consistent with embodiments of the present disclosure.

FIG. 5 is an exemplary graph of resolution KPIs, consistent with embodiments of the present disclosure.

FIG. 6 shows exemplary images and graphs generated by a KPI determination system, consistent with embodiments of the present disclosure.

FIG. 7 is an exemplary graph of resolution KPIs, consistent with embodiments of the present disclosure.

FIG. 8 shows exemplary images and graphs generated by a KPI determination system, consistent with embodiments of the present disclosure.

FIG. 9 is an exemplary graph of resolution KPIs, consistent with embodiments of the present disclosure.

FIG. 10 is an exemplary graph of resolution KPIs, consistent with embodiments of the present disclosure.

FIG. 11 shows exemplary graphs of resolution KPIs, consistent with some embodiments of the present disclosure.

FIG. 12 is a flowchart illustrating an exemplary process of image resolution characterization, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly, and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be provided onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may provide more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

Systems may generate images with an image resolution (e.g., a measurement of the smallest structure that can be captured in the image, the size of the focused e-beam, etc.) that needs to be adjusted. For example, a system may use key performance indicators to determine whether the resolution of an image is too low and whether the image needs to be adjusted to compensate for the resolution.

Typical inspection and metrology systems, however, suffer from constraints. Typical inspection and metrology systems may use key performance indicators that are sensitive to the brightness or contrast of the image, but are not sensitive to the resolution of the image. Typical key performance indicators lack sensitivity to the resolution of an image, especially when the image is relatively sharp (e.g., when the image has details with clearly defined borders).

Some of the disclosed embodiments provide systems and methods that address some or all of these disadvantages by determining and using key performance indicators that are sensitive to image resolution to compensate for image resolution. The disclosed embodiments may include observing a pixel size of a raw image; applying a Fourier transform to the raw image to convert the raw image into a transformed image; applying a function, based on the pixel size, to the transformed image; and determining a key performance indicator of a resolution of the raw image based on results of the applied function, thereby increasing the robustness and reliability of the image resolution characterization.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

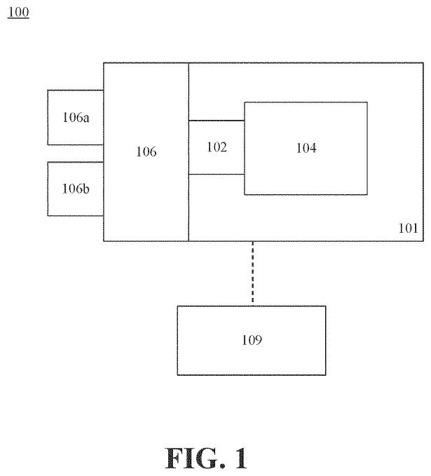

FIG. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries and adapting to different throughputs and resolution requirements.

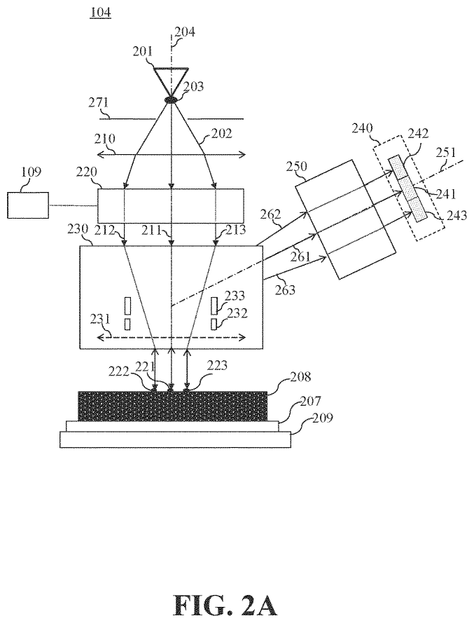

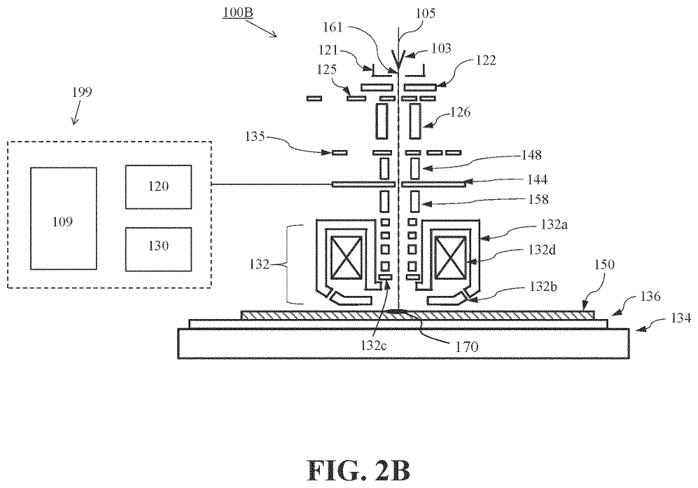

Reference is now made to FIG. 2A, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2A shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principle plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2A). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy ≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2A shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

For example, as shown in FIG. 2B, an electron beam tool 100B (also referred to herein as apparatus 100B) may be a single-beam inspection tool that is used in EBI system 10, consistent with embodiments of the present disclosure. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150.

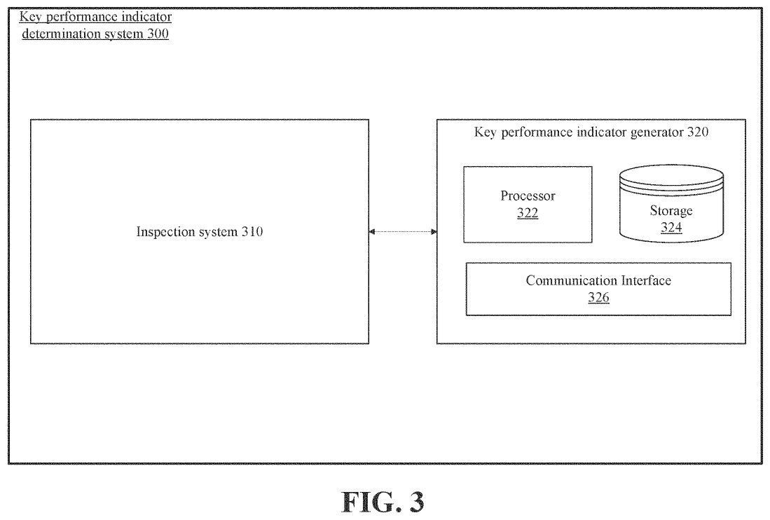

Reference is now made to FIG. 3, a schematic diagram of a key performance indicator (KPI) determination system 300, consistent with embodiments of the present disclosure. KPI system 300 may include an inspection system 310 and a KPI generator 320. While an inspection system 310 is shown and described for purposes of simplicity, it is appreciated that a metrology system can also be used.

Inspection system 310 and KPI generator 320 may be electrically coupled (directly or indirectly) to each other, either physically (e.g., by a cable) or remotely. Inspection system 310 may be the system described with respect to FIGS. 1, 2A, and 2B, used to acquire images of a wafer (see, e.g., sample 208 of FIG. 2A, wafer 150 of FIG. 2B). In some embodiments, KPI determination system 300 may be apart of inspection system 310. In some embodiments, KPI determination system may be a part of a controller (e.g., controller 109).

KPI generator 320 may include one or more processors (e.g., processor 322, an instance of which is used for purposes of simplicity) and a storage 324. The one or more processors can include a generic or specific electronic device capable of manipulating or processing information. For example, the one or more processors may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

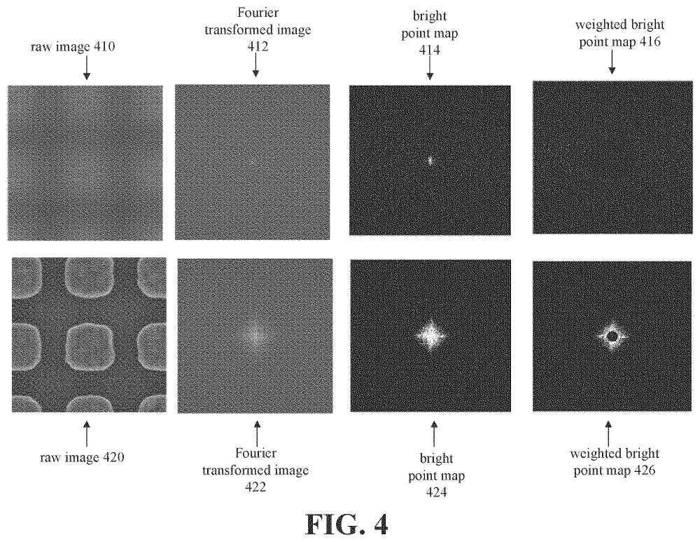

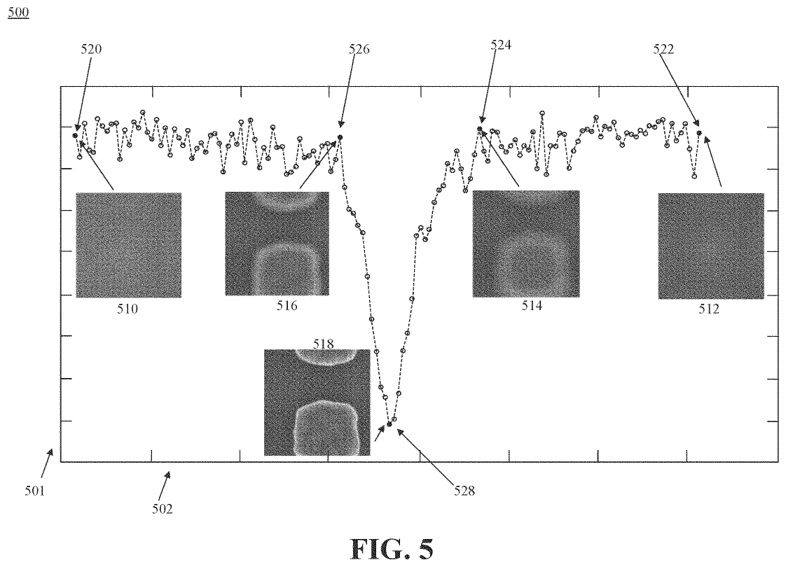

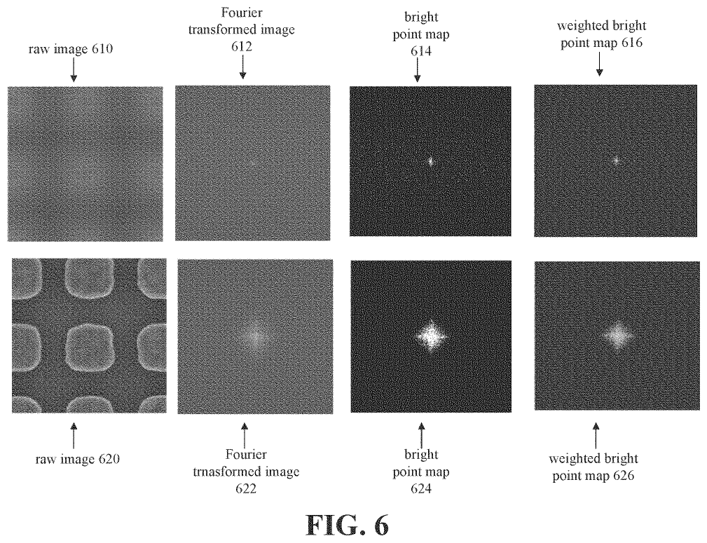

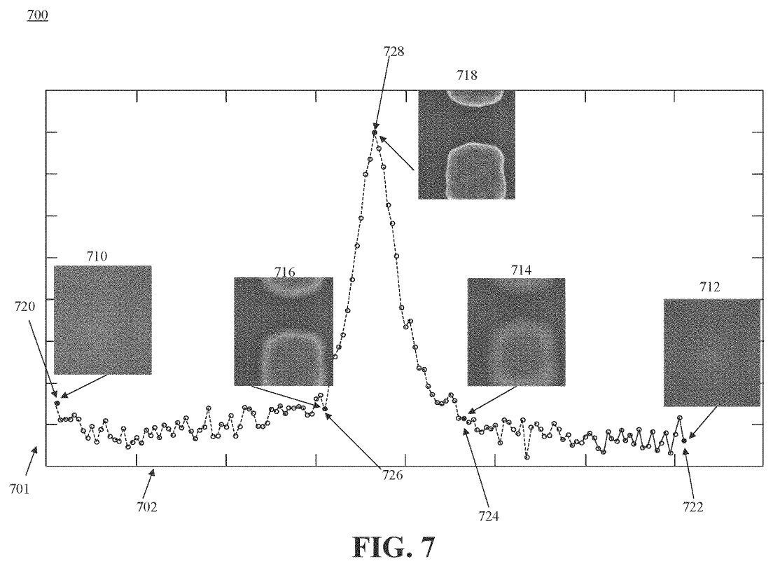

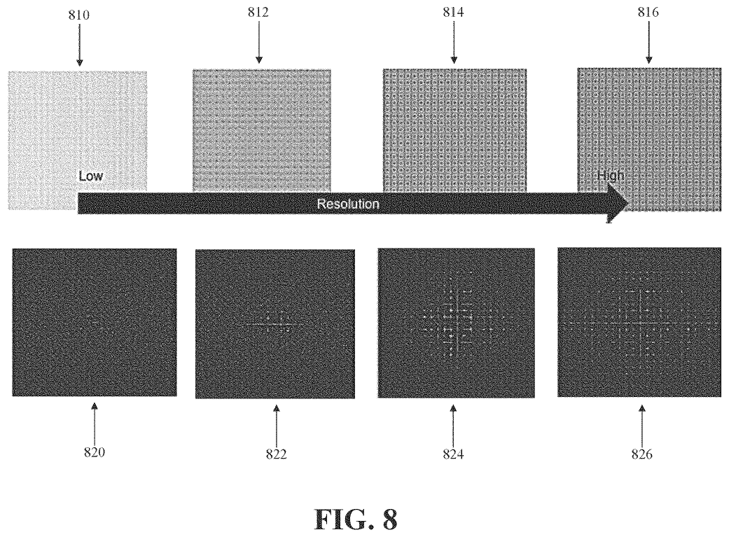

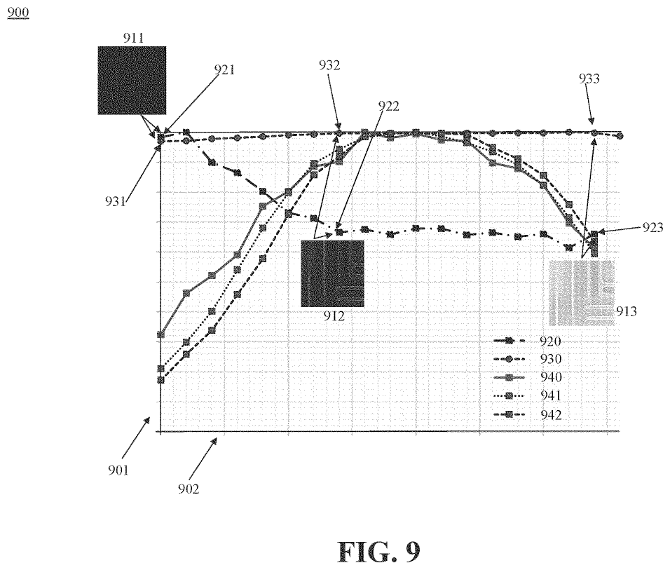

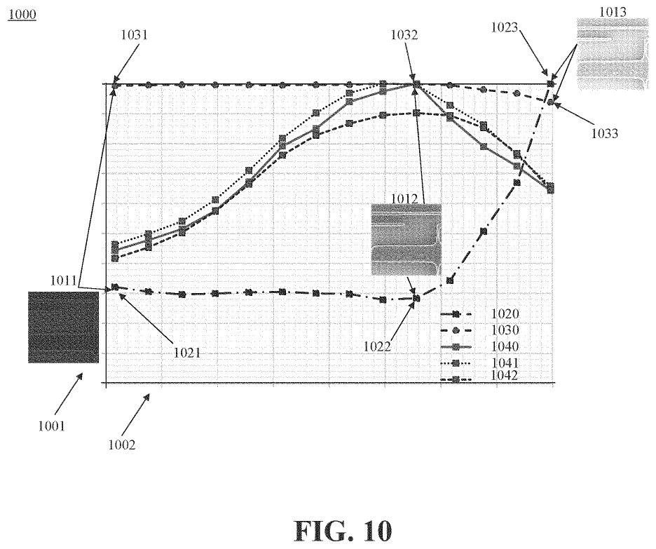

KPI generator 320 may also include a communication interface 326 to receive and send data to inspection system 310. Processor 322 may be configured to receive one or more raw images of a sample from inspection system 310. In some embodiments, inspection system 310 may provide a raw image of a sample to KPI generator 320, and processor 322 of KPI generator 320 may observe a pixel size of the raw image and apply a Fourier transform (e.g., Discrete Fourier transforms (DFT), fast Fourier transforms (FFT), etc.) to the raw image (e.g., images 410 and 420 of FIG. 4; images 510, 512, 514, 516, 518 of FIG. 5; images 610 and 620 of FIG. 6; images 710, 712, 714, 716, 718 of FIG. 7; images 810, 812, 814, 816 of FIG. 8; images 911 and 912 of FIG. 9; images 1011 and 1012 of FIG. 10) to convert the raw image into a transformed image (e.g., images 412 and 422 of FIG. 4; images 612 and 622 of FIG. 6; images 820, 822, 824, 826 of FIG. 8).

In some embodiments, converting the raw image into the transformed image may include obtaining different spatial frequencies from the raw image, where a spatial frequency may be a rate at which features of the raw image change. For example, one spatial frequency may fit features of the raw image and another different spatial frequency may fit other features of the raw image.

In some embodiments, processor 322 may determine a plurality of coordinates in a spatial frequency space, where each coordinate corresponds to a spatial frequency of the raw image. In some embodiments, each determined coordinate may have three variables: an “x” coordinate that describes the spatial frequency of an image in an “x” direction, a “y” coordinate that describes the spatial frequency of the image in a “y” direction, and a “z” coordinate that describes a grey level value of the corresponding x and y coordinates of the transformed image. In some embodiments, the transformed image may be generated by plotting coordinates in a spatial frequency space.

In some embodiments, the z coordinates may be indirectly related to spatial frequencies of the raw image. That is, higher z coordinate values may be consistent with lower spatial frequency values. In some embodiments, the z coordinates may be directly related to the resolution of the raw image. That is, higher z coordinate values may be consistent with higher image resolutions of the raw image.

In some embodiments, processor 322 may determine a subset of the plurality of coordinates with the highest z coordinate values in the spatial frequency space. For example, the subset may include the coordinates with the top 1.5% highest z coordinate values. It should be understood that 1.5% is an example and that other percentages may be used. In some embodiments, processor 322 may generate a bright point map image (e.g., graphs 414 and 424 of FIG. 4; graphs 614 and 624 of FIG. 6; graphs 820, 822, 824, 826 of FIG. 8) by plotting the subset of coordinates.

In some embodiments, processor 322 may apply a function, based on an observed pixel size of the raw image and a resolution of inspection system 310, to the transformed image by applying the function to each coordinate of the subset. In some embodiments, the function may be described as shown in function (1) below:

$$f ( x , y , z ) \qquad ( 1 )$$

where “x” is an x coordinate that describes the spatial frequency of an image in an x direction, “y” is a y coordinate that describes the spatial frequency of the image in a y direction, and “z” is a z coordinate that describes a grey level value of the corresponding x and y coordinates of the transformed the image. For example, processor 322 may plug the coordinates of the subset into a function and generate a weight bright point map (e.g., graphs 416 and 426 of FIG. 4; graphs 616 and 626 of FIG. 6) by plotting the results of the applied function. In some embodiments, different functions may be used based on a pixel size relative to an optical system resolution.

In some embodiments, processor 322 may determine a KPI of resolution of the raw image based on results of the applied function. In some embodiments, processor 322 may determine the KPI by determining a sum of the results of the applied function, as shown in equation (2) below:

$${\sum }_{bright point} f ( x , y , z ) \qquad ( 2 )$$

For example, processor 322 may determine the KPI by determining a sum of the z coordinate values after the function is applied to the coordinates.

In some embodiments, processor 322 may adjust the raw image using the determined KPI to compensate for the resolution of the raw image. In some embodiments, processor 322 may adjust the raw image by adjusting an astigmatism (e.g., in an “x” direction, in a “y” direction) in inspection system 310 based on the determined KPI. In some embodiments, processor 322 may use the determined KPI to adjust focus values in inspection system 310.

Reference is now made to FIG. 4, exemplary images and graphs generated by KPI determination system 300, consistent with embodiments of the present disclosure.

In some embodiments, images 410 and 420 may be generated in an imaging system (e.g., inspection system 310 of FIG. 3) where the imaging system pixel size is equal to or less than the optical system resolution. In some embodiments, image 410 may have greater blurriness, and less sharpness, than image 420. In some embodiments, image 410 may have an image resolution that is less than that of image 420.

In some embodiments, images 410 and 420 may be raw images of a sample. In some embodiments, a processor (e.g., processor 322 of FIG. 3) may apply a Fourier transform (e.g., Discrete Fourier transforms (DFT), fast Fourier transforms (FFT), etc.) to images 410 and 420 to convert images 410 and 420 into transformed images 412 and 422, respectively. For example, the processor may convert image 410 into image 412 by obtaining a plurality of spatial frequencies of image 410, where each spatial frequency of the plurality of spatial frequencies characterizes image 410. In some embodiments, each spatial frequency of the plurality of spatial frequencies may describe image 410, where a spatial frequency may be a rate at which features of image 410 change. For example, one spatial frequency may fit features of image 410 and another different spatial frequency may fit other features of image 410. The processor may convert image 420 into image 422 in a similar manner.

In some embodiments, the processor may determine a plurality of coordinates in a spatial frequency space, where each coordinate corresponds to a spatial frequency of the plurality of spatial frequencies. In some embodiments, each determined coordinate may have three variables: an “x” coordinate that describes the spatial frequency of an image in an “x” direction, a “y” coordinate that describes the spatial frequency of the image in a “y” direction, and a “z” coordinate that describes a grey level value of the corresponding x and y coordinates of the transformed the image. In some embodiments, images 412 and 422 may be generated by plotting coordinates in a spatial frequency space.

In some embodiments, the z coordinates may be indirectly related to spatial frequencies of the raw image. That is, higher z coordinate values may be consistent with lower spatial frequency values. In some embodiments, the z coordinates may be directly related to the resolution of the raw image. That is, higher z coordinate values may be consistent with a higher image resolution of the raw image. For example, image 420 may have a higher image resolution than image 410. As seen in images 412 and 422, image 422 has a greater number of condensed “bright” points in the center of the image than image 412, where the bright points are consistent with higher z coordinate values. Image 412, in contrast, shows more scattered bright points than image 422. This may indicate that image 420 has higher information reliability in lower spatial frequencies than image 410.

In some embodiments, the processor may determine a subset of the plurality of coordinates with the highest z coordinate values in the spatial frequency space. For example, the subset may include coordinates with the top 1.5% highest z coordinate values. It should be understood that 1.5% is an example and that other percentages may be used. In some embodiments, the processor may generate a bright point map graph 414 by plotting the subset of coordinates from image 412. Similarly, the processor may generate a bright point map graph 424 by plotting the subset of coordinates from image 422.

In some embodiments, the processor may apply a function, based on a system pixel size and the optical system resolution, to transformed images 412 and 422 by applying the function to each coordinate of the subset (e.g., by applying the function to each coordinate of graphs 414 and 424, respectively). In some embodiments, the function may describe a relationship of a coordinate distance from the origin coordinate in a frequency space. In the function, “x” is an x coordinate that describes the spatial frequency of an image in an x direction, “y” is a y coordinate that describes the spatial frequency of the image in a y direction, and “z” is a z coordinate that describes a grey level value of the corresponding x and y coordinates of the transformed image. For example, the processor may plug the coordinates of the subset into a function and generate a weight bright point map graph 416 by plotting the results of the function applied to the coordinates of graph 414. Similarly, the processor may plug the coordinates of the subset into a function and generate a weighted bright point map graph 426 by plotting the results of the function applied to the coordinates of graph 424.

In some embodiments, the processor may determine a KPI of resolution of images 410 and 420 based on results of the applied function. In some embodiments, the processor may determine the KPI by determining a sum of the results of the applied function, as shown in equation (2) above, using a function describing a relationship of a coordinate distance from the origin coordinate in a frequency space. For example, the processor may determine the KPI for image 410 by determining a sum of the z coordinate values in graph 416. Similarly, the processor may determine the KPI for image 420 by determining a sum of the z coordinate values in graph 426.

Reference is now made to FIG. 5, an exemplary graph 500 of resolution KPIs generated by KPI determination system 300 of FIG. 3 for various images, consistent with embodiments of the present disclosure.

Graph 500 shows an axis 501 for image resolution KPI values (e.g., determined by KPI determination system 300 of FIG. 3) and an axis 502 for optical lens focus values. Graph 500 shows raw images 510, 512, 514, 516, and 518 of a sample (e.g., sample 208 of FIG. 2A, wafer 150 of FIG. 2B). Graph 500 may correspond to KPIs determined using the function applied to generate graphs 416 and 426 of FIG. 4. For example, the KPIs of graph 500 may be determined by determining a sum of the z coordinate values calculated from the same function used to generate graphs 416 and 426 of FIG. 4.

Graph 500 shows an image resolution KPI 520 of image 510, an image resolution KPI 522 of image 512, an image resolution KPI 524 of image 514, an image resolution KPI 526 of image 516, and an image resolution KPI 528 of image 518. As shown in graph 500, lower KPI values correspond to higher image resolutions. Graph 500 also shows that the methods described above with respect to FIGS. 3 and 4 determine KPIs that are sensitive to image resolution even when the image has higher sharpness (e.g., as shown in image 518). As shown in graph 500, image 518 may have a higher image resolution than images 510, 512, 514, or 516.

Reference is now made to FIG. 6, exemplary images and graphs generated by KPI determination system 300, consistent with embodiments of the present disclosure.

In some embodiments, images 610 and 620 may be generated in an imaging system (e.g., inspection system 310 of FIG. 3) where the imaging system pixel size is equal to or less than the optical system resolution. In some embodiments, image 610 may have greater blurriness, and less sharpness, than image 620. In some embodiments, image 610 may have an image resolution that is less than that of image 620.

In some embodiments, images 610 and 620 may be raw images of a sample. In some embodiments, a processor (e.g., processor 322 of FIG. 3) may apply a Fourier transform (e.g., Discrete Fourier transforms (DFT), fast Fourier transforms (FFT), etc.) to images 610 and 620 to convert images 610 and 620 into transformed images 612 and 622, respectively. For example, the processor may convert image 610 into image 612 by obtaining a plurality of spatial frequencies of image 610, where each spatial frequency of the plurality of spatial frequencies characterizes image 610. In some embodiments, each spatial frequency of the plurality of spatial frequencies may describe image 610, where a spatial frequency may be a rate at which features of image 610 change. For example, one spatial frequency may fit features of image 610 and another different spatial frequency may fit other features of image 610. The processor may convert image 620 into image 622 in a similar manner.

In some embodiments, the processor may determine a plurality of coordinates in a spatial frequency space, where each coordinate corresponds to a spatial frequency of the plurality of spatial frequencies. In some embodiments, each determined coordinate may have three variables: an “x” coordinate that describes the spatial frequency of an image in an “x” direction, a “y” coordinate that describes the spatial frequency of the image in a “y” direction, and a “z” coordinate that describes a grey level value of the corresponding x and y coordinates of the transformed the image. In some embodiments, images 612 and 622 may be generated by plotting coordinates in a spatial frequency space.

In some embodiments, the z coordinates may be indirectly related to spatial frequencies of the raw image. That is, higher z coordinate values may be consistent with lower spatial frequency values. In some embodiments, the z coordinates may be directly related to the resolution of the raw image. That is, higher z coordinate values may be consistent with a higher image resolution of the raw image. For example, image 620 may have a higher image resolution than image 610. As seen in images 612 and 622, image 622 has a greater number of condensed “bright” points in the center of the image than image 612, where the bright points are consistent with higher z coordinate values. Image 612, in contrast, shows more scattered bright points than image 622. Accordingly, images 612 and 622 show that image 420 has lower spatial frequencies, and a higher image resolution and sharpness, than image 610.

In some embodiments, the processor may determine a subset of the plurality of coordinates with the highest z coordinate values in the spatial frequency space. For example, the subset may include the plurality of coordinates with the top 1.5% highest z coordinate values. It should be understood that 1.5% is an example and that other percentages may be used. In some embodiments, the processor may generate a bright point map graph 614 by plotting the subset of coordinates from image 612. Similarly, the processor may generate a bright point map graph 624 by plotting the subset of coordinates from image 622.

In some embodiments, the processor may apply a function, based on a system pixel size and the optical system resolution, to transformed images 612 and 622 by applying the function to each coordinate of the subset (e.g., by applying the function to each coordinate of graphs 614 and 624, respectively). In some embodiments, the function may describe a two-dimensional quadratic function. In the function, “x” is an x coordinate that describes the spatial frequency of an image in an x direction, “y” is a y coordinate that describes the spatial frequency of the image in a y direction, and “z” is a z coordinate that describes a grey level value of the corresponding x and y coordinates of the transformed the image. The function applied to transformed images 612 and 622 may be different from the function applied to transformed images 412 and 422 of FIG. 4. For example, the processor may plug the coordinates of the subset into a function and generate a weight bright point map graph 616 by plotting the results of the function applied to the coordinates of graph 614. Similarly, the processor may plug the coordinates of the subset into a function and generate a weight bright point map graph 626 by plotting the results of the function applied to the coordinates of graph 624. While images 610 and 612 and graph 614 may be the same as images 410 and 412 and graph 414 of FIG. 4, respectively, graph 616 may be different from graph 416 since different functions are applied. Similarly, while images 620 and 622 and graph 624 may be the same as images 420 and 422 and graph 424 of FIG. 4, respectively, graph 626 may be different from graph 426 since different functions are applied.

In some embodiments, the processor may determine a KPI of resolution of images 610 and 620 based on results of the applied function. In some embodiments, the processor may determine the KPI by determining a sum of the results of the applied function, as shown in equation (2) above, using a two-dimensional quadratic function. For example, the processor may determine the KPI for image 610 by determining a sum of the z coordinate values in graph 616. Similarly, the processor may determine the KPI for image 620 by determining a sum of the z coordinate values in graph 626.

Reference is now made to FIG. 7, an exemplary graph 700 of resolution KPIs generated by KPI determination system 300 of FIG. 3 for various images, consistent with embodiments of the present disclosure.

Graph 700 shows an axis 701 for image resolution KPI values (e.g., determined by KPI determination system 300 of FIG. 3) and an axis 702 for optical lens focus values. Graph 700 shows raw images 710, 712, 714, 716, and 718 of a sample (e.g., sample 208 of FIG. 2A, wafer 150 of FIG. 2B). Graph 700 may correspond to KPIs determined using the function applied to generate graphs 616 and 626 of FIG. 6. For example, the KPIs of graph 700 may be determined by determining a sum of the z coordinate values calculated from the same function used to generate graphs 616 and 626 of FIG. 6.

Graph 700 shows an image resolution KPI 720 of image 710, an image resolution KPI 722 of image 712, an image resolution KPI 724 of image 714, an image resolution KPI 726 of image 716, and an image resolution KPI 728 of image 718. As shown in graph 700, higher KPI values correspond to higher image resolutions. Graph 700 also shows that the methods described above with respect to FIGS. 3 and 6 determine KPIs that are sensitive to image resolution even when the image has higher sharpness (e.g., as shown in image 718). As shown in graph 700, image 718 may have a higher image resolution than images 710, 712, 714, or 716.

Reference is now made to FIG. 8, exemplary images and graphs generated by KPI determination system 300, consistent with embodiments of the present disclosure.

In some embodiments, images 810, 812, 814, and 816 may be generated in an imaging system (e.g., inspection system 310 of FIG. 3) where the imaging system pixel size is more than five times greater than the optical system resolution. In some embodiments, images 810, 812, 814, and 816 may increase in image resolution and sharpness and decrease in blurriness (i.e., image 810 may have the lowest image resolution and sharpness and highest blurriness while image 816 may have the highest image resolution and sharpness and lowest blurriness).

In some embodiments, images 810, 812, 814, and 816 may be raw images of a sample. In some embodiments, a processor (e.g., processor 322 of FIG. 3) may apply a Fourier transform (e.g., Discrete Fourier transforms (DFT), fast Fourier transforms (FFT), etc.) to images 810, 812, 814, and 816 to convert images 810, 812, 814, and 816 into transformed images. For example, the processor may convert image 810 by obtaining a plurality of spatial frequencies of image 810, where each spatial frequency of the plurality of spatial frequencies characterizes image 810. In some embodiments, each spatial frequency of the plurality of spatial frequencies may describe image 810, where a spatial frequency may be a rate at which features of image 810 change. For example, one spatial frequency may fit features of image 810 and another different spatial frequency may fit other features of image 810. The processor may convert images 812, 814, and 816 in a similar manner.

In some embodiments, the processor may determine a plurality of coordinates in a spatial frequency space, where each coordinate corresponds to a spatial frequency of the plurality of spatial frequencies. In some embodiments, each determined coordinate may have three variables: an “x” coordinate that describes the spatial frequency of an image in an “x” direction, a “y” coordinate that describes the spatial frequency of the image in a “y” direction, and a “z” coordinate that describes a grey level value of the corresponding x and y coordinates of the transformed the image. In some embodiments, the transformed images may be generated by plotting coordinates in a spatial frequency space.

In some embodiments, the processor may determine a subset of the plurality of coordinates with the highest z coordinate values in the spatial frequency space. For example, the subset may include the plurality of coordinates with the top 1.5% highest z coordinate values. It should be understood that 1.5% is an example and that other percentages may be used. In some embodiments, the processor may generate a bright point map graph 820 by plotting the subset of coordinates from the transformed image of image 810. Similarly, the processor may generate bright point map graphs 822, 824, and 826 by plotting the subset of coordinates from transformed images of images 812, 814, and 816, respectively.

In some embodiments, the z coordinates may be indirectly related to spatial frequencies of the raw image. That is, high z coordinate values may be consistent with low spatial frequency values. In some embodiments, the z coordinates may have a periodic relationship with the resolution of the raw image. That is, low z coordinate values with a periodic distribution may be consistent with a high image resolution of the raw image. For example, image 816 may have a higher image resolution than images 810, 812, and 814. As seen in graphs 820, 822, 824, and 826, the “bright” points in the bright point map graphs may be distributed with a more periodic pattern as the image resolution increases. In contrast, as the image resolution decreases, the bright point map graphs show more scattered bright points. This behavior may be the result of the imaging system pixel size being more than five times greater than the optical system resolution.

Reference is now made to FIG. 9, an exemplary graph 900 of resolution KPIs generated by KPI determination system 300 of FIG. 3 for various images, consistent with embodiments of the present disclosure.

Graph 900 shows an axis 901 for normalized image resolution KPI values (e.g., determined by KPI determination system 300 of FIG. 3) and an axis 902 for image brightness values. Graph 900 shows raw images 911, 912, and 913 of a sample (e.g., sample 208 of FIG. 2A, wafer 150 of FIG. 2B). Graph 900 may include curve 920 corresponding to normalized KPIs of FIG. 5 and curve 930 corresponding to normalized KPIs of FIG. 7. As shown by curves 920 and 930, point 921 of curve 920 and point 931 of curve 930 correspond to normalized KPIs of image 911. As shown by curves 920 and 930, point 922 of curve 920 and point 932 of curve 930 correspond to normalized KPIs of image 912. As shown by curves 920 and 930, point 923 of curve 920 and point 933 of curve 930 correspond to normalized KPIs of image 913. Graph 900 may include curves 940-942 corresponding to normalized KPIs of typical KPI determination methods.

As shown in graph 900, image 913 may have a higher brightness than image 912, while image 912 may have a higher brightness than image 911. Curves 920 and 930 show that the KPI determination methods described above are advantageously less sensitive (e.g., not sensitive) to changes in brightness as compared to the typical methods shown by curves 940-942. In other words, graph 900 may show that the image resolution KPIs determined by methods described in FIGS. 3-7 are independent of changes in image brightness.

Reference is now made to FIG. 10, an exemplary graph 1000 of resolution KPIs generated by KPI determination system 300 of FIG. 3 for various images, consistent with embodiments of the present disclosure.

Graph 1000 shows an axis 1001 for normalized image resolution KPI values (e.g., determined by KPI determination system 300 of FIG. 3) and an axis 1002 for image contrast values. Graph 1000 shows raw images 1011, 1012, and 1013 of a sample (e.g., sample 208 of FIG. 2A, wafer 150 of FIG. 2B). Graph 1000 may include curve 1020 corresponding to normalized KPIs of FIG. 5 and curve 1030 corresponding to normalized KPIs of FIG. 7. As shown by curves 1020 and 1030, point 1021 of curve 1020 and point 1031 of curve 1030 correspond to normalized KPIs of image 1011. As shown by curves 1020 and 1030, point 1022 of curve 1020 and point 1032 of curve 1030 correspond to normalized KPIs of image 1012. As shown by curves 1020 and 1030, point 1023 of curve 1020 and point 1033 of curve 1030 correspond to normalized KPIs of image 1013. Graph 1000 may include curves 1040 corresponding to normalized KPIs of typical KPI determination methods.

As shown in graph 1000, image 1013 may have a higher contrast than image 1012, while image 1012 may have a higher contrast than image 1011. Curves 1020 and 1030 show that the KPI determination methods described above are advantageously less sensitive (e.g., not sensitive) to changes in contrast as compared to the typical methods shown by curves 1040. In other words, graph 1000 may show that the image resolution KPIs determined by methods described in FIGS. 3-7 are independent of changes in image contrast.

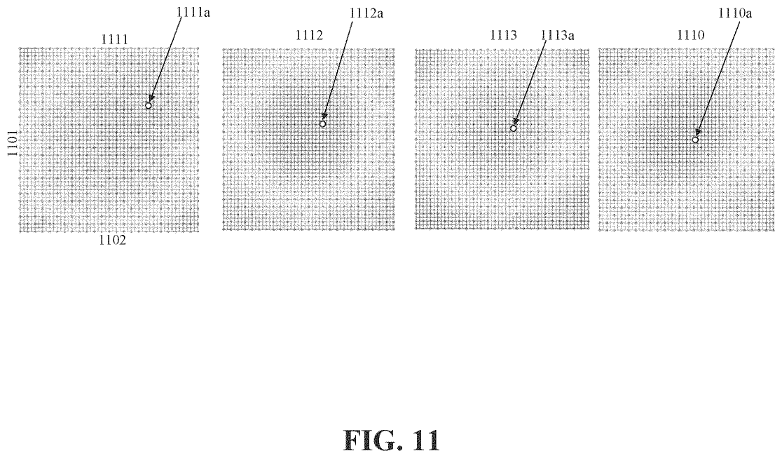

Reference is now made to FIG. 11, showing exemplary graphs 1110, 1111, 1112, and 1113 of resolution KPIs for various images.

Graphs 1110, 1111, 1112, and 1113 each have an axis 1101 for an x-direction astigmatism and an axis 1102 for a y-direction astigmatism. The gradients in each of graphs 1110, 1111, 1112, and 1113 correspond to resolution KPIs. Graph 1110 may correspond to resolution KPIs based on an actual measured resolution of an image, graph 1111 may correspond to resolution KPIs determined by typical KPI determination methods, graph 1112 may correspond to resolution KPIs determined using the function applied in FIGS. 4-5, and graph 1113 may correspond to resolution KPIs determined using the function applied in FIGS. 6-7.

For the same image, graph 1110 may show an actual resolution KPI 1110a, graph 1111 may show a determined resolution KPI 1111a, graph 1112 may show a determined resolution KPI 1112a, and graph 1113 may show a determined resolution KPI 1113a. As shown in graphs 1110-1113, the KPI determination methods described in FIGS. 3-7 are advantageously more accurate than typical KPI determination methods. That is, resolution KPIs 1112a and 1113a are closer than resolution KPI 1111a to the value of resolution KPI 1110a.

The hardware in inspection systems that adjusts astigmatism in the x direction and the hardware that adjusts astigmatism in the y direction are orthogonal. Accordingly, a robust and reliable KPI determination method should be orthogonal (e.g., the determined KPIs should have a symmetric, circular distribution in a gradient graph). Graphs 1112 and 1113 show gradients that are more circular and symmetrical than the gradient in graph 1111, meaning that the x and y direction astigmatisms in graphs 1112 and 1113 are more orthogonal than that of graph 1111. Typical KPI determination methods, such as the method use to generate graph 1111, may result in crosstalk during astigmatism correction, even when the image resolution is higher quality. The KPI determination methods described in FIGS. 3-7 may reduce crosstalk during astigmatism correction since it shows higher orthogonality than typical KPI determination methods. Advantageously, the KPI determination methods described in FIGS. 3-7 may adjust an astigmatism in one direction without affecting the astigmatism in another direction.

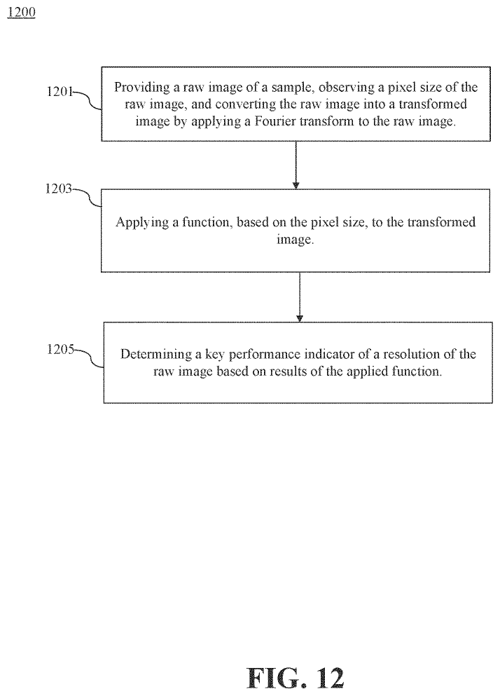

Reference is now made to FIG. 12, a flowchart illustrating an exemplary process 1200 of image resolution characterization, consistent with embodiments of the present disclosure. The steps of method 1200 can be performed by a system (e.g., KPI determination system 300 of FIG. 3) executing on or otherwise using the features of a computing device (e.g., controller 109 of FIG. 1, KPI determination system 300 of FIG. 3, or any components thereof) for purposes of illustration. It is appreciated that the illustrated method 1200 can be altered to modify the order of steps and to include additional steps that may be performed by the system.

At step 1201, an inspection system (e.g., inspection system 310 of FIG. 3) may provide a raw image of a sample to a KPI generator (e.g., KPI generator 320 of FIG. 3), and a processor (e.g., processor 322 of FIG. 3) may observe a pixel size of the raw image and apply a Fourier transform (e.g., Discrete Fourier transforms (DFT), fast Fourier transforms (FFT), etc.) to the raw image (e.g., images 410 and 420 of FIG. 4; images 510, 512, 514, 516, 518 of FIG. 5; images 610 and 620 of FIG. 6; images 710, 712, 714, 716, 718 of FIG. 7; images 810, 812, 814, 816 of FIG. 8; images 911 and 912 of FIG. 9; images 1011 and 1012 of FIG. 10) to convert the raw image into a transformed image (e.g., images 412 and 422 of FIG. 4; images 612 and 622 of FIG. 6; images 820, 822, 824, 826 of FIG. 8).

In some embodiments, converting the raw image into the transformed image may include obtaining a plurality of spatial frequencies of the raw image, where each spatial frequency of the plurality of spatial frequencies characterizes the raw image. In some embodiments, each spatial frequency of the plurality of spatial frequencies may describe the raw image, where a spatial frequency may be a rate at which features of the raw image change. For example, one spatial frequency that fits features of the raw image and another different spatial frequency may fit other features of the raw image.

In some embodiments, the system may determine a plurality of coordinates in a spatial frequency space, where each coordinate corresponds to a spatial frequency of the plurality of spatial frequencies. In some embodiments, each determined coordinate may have three variables: an “x” coordinate that describes the spatial frequency of an image in an “x” direction, a “y” coordinate that describes the spatial frequency of the image in a “y” direction, and a “z” coordinate that describes a grey level value of the corresponding x and y coordinates of the transformed the image. In some embodiments, the transformed image may be generated by plotting coordinates in a spatial frequency space.

In some embodiments, the z coordinates may be indirectly related to spatial frequencies of the raw image. That is, higher z coordinate values may be consistent with lower spatial frequency values. In some embodiments, the z coordinates may be directly related to the resolution of the raw image. That is, higher z coordinate values may be consistent with higher image resolution of the raw image.

In some embodiments, the system may determine a subset of the plurality of coordinates with the highest z coordinate values in the spatial frequency space. For example, the subset may include the plurality of coordinates with the top 1.5% highest z coordinate values. It should be understood that 1.5% is an example and that other percentages may be used. In some embodiments, processor 322 may generate a bright point map graph (e.g., graphs 414 and 424 of FIG. 4; graphs 614 and 624 of FIG. 6; graphs 820, 822, 824, 826 of FIG. 8) by plotting the subset of coordinates.

At step 1203, the system may apply a function, based on the pixel size, to the transformed image by applying the function to each coordinate of the subset. For example, the processor may plug the coordinates of the subset into a function and generate a weight bright point map (e.g., graphs 416 and 426 of FIG. 4; graphs 616 and 626 of FIG. 6) by plotting the results of the applied function.

At step 1205, the system may determine a KPI of resolution of the raw image based on results of the applied function. In some embodiments, the system may determine the KPI by determining a sum of the results of the applied function. For example, the system may determine the KPI by determining a sum of the z coordinate values after the function is applied to the coordinates.

In some embodiments, the system may adjust the raw image using the determined KPI to compensate for the resolution of the raw image. In some embodiments, processor 322 may adjust the raw image by adjusting an astigmatism (e.g., in an “x” direction, in a “y” direction) in the inspection system based on the determined KPI. In some embodiments, the system may use the determined KPI to adjust focus values in an inspection system.

A non-transitory computer readable medium may be provided that stores instructions for a processor of a controller (e.g., controller 109 of FIG. 1) for controlling the electron beam tool or other systems (e.g., KPI determination system 300 of FIG. 3) of other systems and servers, or components thereof, consistent with embodiments in the present disclosure. These instructions may allow the one or more processors to carry out image resolution characterization, image processing, data processing, beamlet scanning, graphical display, operations of a charged particle beam apparatus, or another imaging device, or the like. In some embodiments, the non-transitory computer readable medium may be provided that stores instructions for a processor to perform the steps of process 1200. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:

1. A method of characterizing optical resolution comprising:
providing a raw image of a sample;
observing a pixel size of the raw image;
converting the raw image into a transformed image by applying a Fourier transform to the raw image;
applying a function, based on the pixel size, to the transformed image; and
determining a key performance indicator of a resolution of the raw image based on results of the applied function.

2. The method of clause 1, wherein converting the raw image into the transformed image comprises: obtaining a plurality of spatial frequencies of the raw image, wherein each spatial frequency of the plurality of spatial frequencies characterizes the raw image; and determining a plurality of coordinates in a spatial frequency space, wherein each coordinate of the plurality of coordinates corresponds to a spatial frequency of the plurality of spatial frequencies.

3. The method of clause 2, further comprising determining a subset of the plurality of coordinates, wherein each coordinate of the subset comprises a value that is in a highest percentile of the plurality of coordinates.

4. The method of clause 3, wherein applying the function to the transformed image comprises applying the function to each coordinate of the subset.

5. The method of clause 4, wherein determining the key performance indicator of the resolution of the raw image comprises determining a sum of the results of the applied function.

6. The method of any one of clauses 3-5, wherein the value of each coordinate of the subset comprises a grey scale value.

7. The method of any one of clauses 3-6, wherein the values of the subset are indirectly related to the plurality of spatial frequencies.

8. The method of any one of clauses 3-7, wherein the values of the subset are directly related to the resolution of the raw image.

9. The method of any one of clauses 1-8, wherein the key performance indicator of the resolution is independent of a brightness of the raw image or a contrast of the raw image.

10. The method of any one of clauses 1-9, further comprising adjusting the raw image using the key performance indicator of the resolution to compensate for the resolution.

11. The method of clause 10, wherein adjusting the raw image comprises adjusting an astigmatism in an imaging system.

12. A system of characterizing optical resolution comprising:
one or more processors configured to execute instructions to cause the system to perform:
providing a raw image of a sample;
observing a pixel size of the raw image;
converting the raw image into a transformed image by applying a Fourier transform to the raw image;
applying a function, based on the pixel size, to the transformed image; and
determining a key performance indicator of a resolution of the raw image based on results of the applied function.

13. The system of clause 12, wherein converting the raw image into the transformed image comprises:
obtaining a plurality of spatial frequencies of the raw image, wherein each spatial frequency of the plurality of spatial frequencies characterizes the raw image; and
determining a plurality of coordinates in a spatial frequency space, wherein each coordinate of the plurality of coordinates corresponds to a spatial frequency of the plurality of spatial frequencies.

14. The system of clause 13, wherein the one or more processors are configured to execute instructions to cause the system to further perform determining a subset of the plurality of coordinates, wherein each coordinate of the subset comprises a value that is in a highest percentile of the plurality of coordinates.

15. The system of clause 14, wherein applying the function to the transformed image comprises applying the function to each coordinate of the subset.

16. The system of clause 15, wherein determining the key performance indicator of the resolution of the raw image comprises determining a sum of the results of the applied function.

17. The system of any one of clauses 14-16, wherein the value of each coordinate of the subset comprises a grey scale value.

18. The system of any one of clauses 14-17, wherein the values of the subset are indirectly related to the plurality of spatial frequencies.

19. The system of any one of clauses 14-18, wherein the values of the subset are directly related to the resolution of the raw image.

20. The system of any one of clauses 12-19, wherein the key performance indicator of the resolution is independent of a brightness of the raw image or a contrast of the raw image.

21. The system of any one of clauses 12-20, wherein the one or more processors are configured to execute instructions to cause the system to further perform adjusting the raw image using the key performance indicator of the resolution to compensate for the resolution.

22. The system of clause 21, wherein adjusting the raw image comprises adjusting an astigmatism in an imaging system.

23. A non-transitory computer readable medium including a set of instructions that is executable by one or more processors of an apparatus to cause the apparatus to perform a method comprising:
providing a raw image of a sample;
observing a pixel size of the raw image;
converting the raw image into a transformed image by applying a Fourier transform to the raw image;
applying a function, based on the pixel size, to the transformed image; and
determining a key performance indicator of a resolution of the raw image based on results of the applied function.

24. The non-transitory computer readable medium of clause 23, wherein converting the raw image into the transformed image comprises:
obtaining a plurality of spatial frequencies of the raw image, wherein each spatial frequency of the plurality of spatial frequencies characterizes the raw image; and
determining a plurality of coordinates in a spatial frequency space, wherein each coordinate of the plurality of coordinates corresponds to a spatial frequency of the plurality of spatial frequencies.

25. The non-transitory computer readable medium of clause 24, wherein the set of instructions that is executable by one or more processors of the apparatus to cause the apparatus to further perform determining a subset of the plurality of coordinates, wherein each coordinate of the subset comprises a value that is in a highest percentile of the plurality of coordinates.

26. The non-transitory computer readable medium of clause 25, wherein applying the function to the transformed image comprises applying the function to each coordinate of the subset.

27. The non-transitory computer readable medium of clause 26, wherein determining the key performance indicator of the resolution of the raw image comprises determining a sum of the results of the applied function.

28. The non-transitory computer readable medium of any one of clauses 25-27, wherein the value of each coordinate of the subset comprises a grey scale value.

29. The non-transitory computer readable medium of any one of clauses 25-28, wherein the values of the subset are indirectly related to the plurality of spatial frequencies.

30. The non-transitory computer readable medium of any one of clauses 25-29, wherein the values of the subset are directly related to the resolution of the raw image.

31. The non-transitory computer readable medium of any one of clauses 23-30, wherein the key performance indicator of the resolution is independent of a brightness of the raw image or a contrast of the raw image.

32. The non-transitory computer readable medium of any one of clauses 23-31, wherein the set of instructions that is executable by one or more processors of the apparatus to cause the apparatus to further perform adjusting the raw image using the key performance indicator of the resolution to compensate for the resolution.

33. The non-transitory computer readable medium of clause 10, wherein adjusting the raw image comprises adjusting an astigmatism in an imaging system.

34. A method comprising:
providing an image of a sample;
observing a pixel size of the image;
converting the image into a transformed image;
applying a function, based on the pixel size, to the transformed image; and
determining a key performance indicator of a resolution of the image by applying the function to the transformed image.

35. The method of clause 34, wherein converting the image into the transformed image comprises:
obtaining a plurality of spatial frequencies of the image, wherein each spatial frequency of the plurality of spatial frequencies characterizes the image; and
determining a plurality of coordinates in a spatial frequency space, wherein each coordinate of the plurality of coordinates corresponds to a spatial frequency of the plurality of spatial frequencies.

36. The method of clause 35, further comprising determining a subset of the plurality of coordinates, wherein each coordinate of the subset comprises a value that is in a highest percentile of the plurality of coordinates.

37. The method of clause 36, wherein applying the function to the transformed image comprises applying the function to each coordinate of the subset.

38. The method of clause 37, wherein determining the key performance indicator of the resolution of the image comprises determining a sum of the results of the applied function.

39. The method of any one of clauses 36-38, wherein the value of each coordinate of the subset comprises a grey scale value.

40. The method of any one of clauses 36-39, wherein the values of the subset are indirectly related to the plurality of spatial frequencies.

41. The method of any one of clauses 36-40, wherein the values of the subset are directly related to the resolution of the image.

42. The method of any one of clauses 34-41, wherein the key performance indicator of the resolution is independent of a brightness of the image or a contrast of the image.

43. The method of any one of clauses 34-42, further comprising adjusting the image using the key performance indicator of the resolution to compensate for the resolution.

44. The method of clause 43, wherein adjusting the image comprises adjusting an astigmatism in an imaging system.

45. A system comprising:
one or more processors configured to execute instructions to cause the system to perform:
providing an image of a sample;
observing a pixel size of the image;
converting the image into a transformed image;
applying a function, based on the pixel size, to the transformed image; and
determining a key performance indicator of a resolution of the image by applying the function to the transformed image.

46. The system of clause 45, wherein converting the image into the transformed image comprises:
obtaining a plurality of spatial frequencies of the image, wherein each spatial frequency of the plurality of spatial frequencies characterizes the image; and
determining a plurality of coordinates in a spatial frequency space, wherein each coordinate of the plurality of coordinates corresponds to a spatial frequency of the plurality of spatial frequencies.

47. The system of clause 46, wherein the one or more processors are configured to execute instructions to cause the system to further perform determining a subset of the plurality of coordinates, wherein each coordinate of the subset comprises a value that is in a highest percentile of the plurality of coordinates.

48. The system of clause 47, wherein applying the function to the transformed image comprises applying the function to each coordinate of the subset.

49. The system of clause 48, wherein determining the key performance indicator of the resolution of the image comprises determining a sum of the results of the applied function.

50. The system of any one of clauses 47-49, wherein the value of each coordinate of the subset comprises a grey scale value.

51. The system of any one of clauses 47-50, wherein the values of the subset are indirectly related to the plurality of spatial frequencies.

52. The system of any one of clauses 47-51, wherein the values of the subset are directly related to the resolution of the image.

53. The system of any one of clauses 45-52, wherein the key performance indicator of the resolution is independent of a brightness of the image or a contrast of the image.

54. The system of any one of clauses 45-53, wherein the one or more processors are configured to execute instructions to cause the system to further perform adjusting the image using the key performance indicator of the resolution to compensate for the resolution.

55. The system of clause 54, wherein adjusting the image comprises adjusting an astigmatism in an imaging system.

56. A non-transitory computer readable medium including a set of instructions that is executable by one or more processors of an apparatus to cause the apparatus to perform a method comprising:
providing an image of a sample;
observing a pixel size of the image;
converting the image into a transformed image;
applying a function, based on the pixel size, to the transformed image; and
determining a key performance indicator of a resolution of the image by applying the function to the transformed image.

57. The non-transitory computer readable medium of clause 56, wherein converting the image into the transformed image comprises:
obtaining a plurality of spatial frequencies of the image, wherein each spatial frequency of the plurality of spatial frequencies characterizes the image; and
determining a plurality of coordinates in a spatial frequency space, wherein each coordinate of the plurality of coordinates corresponds to a spatial frequency of the plurality of spatial frequencies.

58. The non-transitory computer readable medium of clause 57, wherein the set of instructions that is executable by one or more processors of the apparatus to cause the apparatus to further perform determining a subset of the plurality of coordinates, wherein each coordinate of the subset comprises a value that is in a highest percentile of the plurality of coordinates.

59. The non-transitory computer readable medium of clause 58, wherein applying the function to the transformed image comprises applying the function to each coordinate of the subset.

60. The non-transitory computer readable medium of clause 59, wherein determining the key performance indicator of the resolution of the image comprises determining a sum of the results of the applied function.

61. The non-transitory computer readable medium of any one of clauses 58-60, wherein the value of each coordinate of the subset comprises a grey scale value.

62. The non-transitory computer readable medium of any one of clauses 58-61, wherein the values of the subset are indirectly related to the plurality of spatial frequencies.

63. The non-transitory computer readable medium of any one of clauses 58-62, wherein the values of the subset are directly related to the resolution of the image.

64. The non-transitory computer readable medium of any one of clauses 56-63, wherein the key performance indicator of the resolution is independent of a brightness of the image or a contrast of the image.

65. The non-transitory computer readable medium of any one of clauses 56-64, wherein the set of instructions that is executable by one or more processors of the apparatus to cause the apparatus to further perform adjusting the image using the key performance indicator of the resolution to compensate for the resolution.

66. The non-transitory computer readable medium of clause 65, wherein adjusting the image comprises adjusting an astigmatism in an imaging system.

It will be appreciated that the embodiments of the present disclosure are not limited to the exact construction that has been described above and illustrated in the accompanying drawings, and that various modifications and changes may be made without departing from the scope thereof.

1. A system of characterizing optical resolution comprising:
one or more processors configured to execute instructions to cause the system to perform:
providing a raw image of a sample;
observing a pixel size of the raw image;
converting the raw image into a transformed image by applying a Fourier transform to the raw image;
applying a function, based on the pixel size, to the transformed image; and
determining a key performance indicator of a resolution of the raw image based on results of the applied function.

2. The system of claim 1, wherein converting the raw image into the transformed image comprises:
obtaining a plurality of spatial frequencies of the raw image, wherein each spatial frequency of the plurality of spatial frequencies characterizes the raw image; and
determining a plurality of coordinates in a spatial frequency space, wherein each coordinate of the plurality of coordinates corresponds to a spatial frequency of the plurality of spatial frequencies.

3. The system of claim 2, wherein the one or more processors are configured to execute instructions to cause the system to further perform determining a subset of the plurality of coordinates, wherein each coordinate of the subset comprises a value that is in a highest percentile of the plurality of coordinates.

4. The system of claim 3, wherein applying the function to the transformed image comprises applying the function to each coordinate of the subset.

5. The system of claim 4, wherein determining the key performance indicator of the resolution of the raw image comprises determining a sum of the results of the applied function.

6. The system of claim 3, wherein the value of each coordinate of the subset comprises a grey scale value.

7. The system of claim 3, wherein the values of the subset are indirectly related to the plurality of spatial frequencies.

8. The system of claim 3, wherein the values of the subset are directly related to the resolution of the raw image.

9. The system of claim 1, wherein the key performance indicator of the resolution is independent of a brightness of the raw image or a contrast of the raw image.

10. The system of claim 1, wherein the one or more processors are configured to execute instructions to cause the system to further perform adjusting the raw image using the key performance indicator of the resolution to compensate for the resolution.

11. The system of claim 10, wherein adjusting the raw image comprises adjusting an astigmatism in an imaging system.

12. A non-transitory computer readable medium including a set of instructions that is executable by one or more processors of an apparatus to cause the apparatus to perform a method comprising:
providing a raw image of a sample;
observing a pixel size of the raw image;
converting the raw image into a transformed image by applying a Fourier transform to the raw image;
applying a function, based on the pixel size, to the transformed image; and
determining a key performance indicator of a resolution of the raw image based on results of the applied function.

13. The non-transitory computer readable medium of claim 12, wherein converting the raw image into the transformed image comprises:
obtaining a plurality of spatial frequencies of the raw image, wherein each spatial frequency of the plurality of spatial frequencies characterizes the raw image; and
determining a plurality of coordinates in a spatial frequency space, wherein each coordinate of the plurality of coordinates corresponds to a spatial frequency of the plurality of spatial frequencies.

14. The non-transitory computer readable medium of claim 13, wherein the set of instructions that is executable by one or more processors of the apparatus to cause the apparatus to further perform determining a subset of the plurality of coordinates, wherein each coordinate of the subset comprises a value that is in a highest percentile of the plurality of coordinates.

15. The non-transitory computer readable medium of claim 14, wherein applying the function to the transformed image comprises applying the function to each coordinate of the subset.

16. A non-transitory computer readable medium including a set of instructions that is executable by one or more processors of an apparatus to cause the apparatus to perform a method comprising:
providing an image of a sample;
observing a pixel size of the image;
converting the image into a transformed image;
applying a function, based on the pixel size, to the transformed image; and
determining a key performance indicator of a resolution of the image by applying the function to the transformed image.

17. The non-transitory computer readable medium of claim 16, wherein converting the image into the transformed image comprises:
obtaining a plurality of spatial frequencies of the image, wherein each spatial frequency of the plurality of spatial frequencies characterizes the image; and
determining a plurality of coordinates in a spatial frequency space, wherein each coordinate of the plurality of coordinates corresponds to a spatial frequency of the plurality of spatial frequencies.

18. The non-transitory computer readable medium of claim 17, wherein the set of instructions that is executable by one or more processors of the apparatus to cause the apparatus to further perform determining a subset of the plurality of coordinates, wherein each coordinate of the subset comprises a value that is in a highest percentile of the plurality of coordinates.

19. The non-transitory computer readable medium of claim 18, wherein applying the function to the transformed image comprises applying the function to each coordinate of the subset.

20. The non-transitory computer readable medium of claim 19, wherein determining the key performance indicator of the resolution of the image comprises determining a sum of results of the applied function.
